(19) United States
(12) Patent Application Publication
(10) Pub. No.: US 2010/0248467 A1
(43) Pub. Date: Sep. 30, 2010

(54) METHOD FOR FABRICATING NONVOLATILE MEMORY DEVICE

(76) Inventors: Tae-Hyoung Kim, Gyeonggi-do (KR); Myung-Ok Kim, Gyeonggi-do (KR)

Correspondence Address: IP & T Law Firm PLC, 7700 Little River Turnpike, Suite 207, Annandale, VA, 22003, US

(21) Appl. No.: 12/493,706

(22) Filed: Jun. 29, 2009

(30) Foreign Application Priority Data
Mar. 30, 2009 (KR) 10-2009-0026860

(51) Int. Cl. H01L 21/28

(52) U.S. Cl. 438/593; 438/594; 257/E21.21; 257/E21.422

(57) ABSTRACT

Disclosed is a method for fabricating a nonvolatile memory device having a stacked gate structure in which a floating gate, a charge blocking layer, and a control gate are sequentially stacked. The method includes forming a first conductive layer for floating gate over a substrate; forming a charge blocking layer and a second conductive layer for control gate over a resulting structure including the first conductive layer; forming an etch mask pattern over the second conductive layer; performing a primary etch process on the second conductive layer until the charge blocking layer is exposed; forming a passivation layer on a sidewall of the second conductive layer exposed by the primary etch process; and performing a secondary etch process on the charge blocking layer and the first conductive layer.

### CROSS-REFERENCE TO RELATED APPLICATIONS

The present invention claims priority of Korean patent application number 10-2009-0026860, filed on Mar. 30, 2009, the disclosure of which is incorporated herein by reference in its entirety.

### BACKGROUND OF THE INVENTION

The present invention relates to a fabrication technology of semiconductor integrated circuit, and more particularly, to a method for fabricating a nonvolatile memory device having a stacked gate structure in which a floating gate, a charge blocking layer, and a control gate are sequentially stacked.

As it is well known, a cell transistor of a nonvolatile memory device such as a flash memory has a stacked gate structure in which a tunnel insulation layer, a floating gate, a charge blocking layer, and a control gate are sequentially stacked on a semiconductor substrate.

As a cell size in integration of semiconductor devices gets smaller, a critical dimension (CD) of a gate pattern of a cell transistor also decreases and an aspect ratio of the pattern increases.

FIGS. 1A to 1C are perspective views illustrating an etch process for forming a gate pattern of a cell transistor in a flash memory. Referring to FIG. 1A, a floating gate conductive layer 104 is formed on a substrate 102. A first tunnel insulation layer 103 is formed between the first floating gate conductive layer 104 and the substrate 102. The top and sides of the first floating gate conductive layer 104 are covered with a first oxide-nitride-oxide (ONO) layer 105 that functions as a charge blocking layer. The first ONO layer 105 includes an oxide layer 1051, a nitride layer 1052, and an oxide layer 1053. A first control gate conductive layer 106 is formed on the first floating gate conductive layer 104. Typically, the first floating gate conductive layer 104 and the first control gate conductive layer 106 are formed of polysilicon.

In such a state, an etch process for gate patterning is performed. FIG. 1A illustrates the first control gate conductive layer 106 that is etched until the first ONO layer 105 is exposed, in such a state that a first etch mask 107 is formed. Typically, the first etch mask 107 includes a tetra-ethyl-ortho-silicate (TEOS) thin film.

FIG. 1B illustrates a state where the first control gate conductive layer 106 remaining after etching the first ONO layer 105 is also etched. Through such an etch process, the first ONO layer becomes a second ONO layer 105A including a primarily etched oxide pattern 1051A, a primarily etched nitride pattern 1052A, and a primarily etched oxide pattern 1053A. The first control gate conductive layer 106 becomes a second control gate conductive layer 106A whose sidewalls are lost. The first etch mask 107 is also partially etched to be a second etch mask 107A. Furthermore, the first floating gate conductive layer 104A becomes a second floating gate conductive layer 104B whose upper portion is etched. FIG. 1C illustrates a final floating gate pattern 104B that is formed by etching the second floating gate conductive layer 104A surrounded by the second ONO layer 105A. Through such an etch process, the second ONO layer 105A becomes a third ONO layer 105B including a secondarily etched oxide pattern 1051B, a secondarily etched nitride pattern 1052B, and a secondarily etched oxide pattern 1053B. The second control gate conductive layer 106A becomes a third control gate conductive layer 106B whose lower portion is etched. The second etch mask 107A is also partially etched to be a third etch mask 107B.

However, the sidewalls of the first control gate conductive layer 106 are lost in a subsequent etch process for etching the first control gate conductive layer 106 until the first ONO layer 105 is exposed. Thus, a gate pattern having a positive slope profile is formed, and a top CD of the control gate becomes small, resulting in degradation of a sheet resistance (Rs).

FIGS. 2A to 2C are images showing gates of cell transistors in the conventional flash memory, specifically showing profiles of gate patterns according to design rules. More specifically, FIG. 2A shows a profile of a gate pattern according to a 41-nm design rule. A CD of a TEOS etch mask (hard mask) is 41 nm, but a top CD of the control gate (CG) P2 is 34 nm. That is, it can be seen that a CD loss of the control gate (CG) P2 is approximately 7 nm. FIG. 2B shows a profile of a gate pattern according to a 32-nm design rule. It can be seen that a CD loss of the top of the control gate (CG) P2 is approximately 10 nm. FIG. 2C shows a profile of a gate pattern according to a 24-nm design rule. It can be seen that a CD loss of the top of the control gate (CG) P2 is approximately 11 nm.

As the device becomes smaller and smaller, the CD loss of the top of the control gate worsens. As the device becomes highly integrated, a concern over resistance of the control gate is raised.

The first etch mask is typically formed of TEOS. During the etching of the ONO layer having a similar etch rate, the thickness loss of the TEOS etch mask becomes great. Consequently, the first TEOS etch mask 107 is formed thickly in order to obtain high etch masking capability. When the first TEOS etch mask 107 is formed thickly, the pattern becomes higher, causing severe wiggling of the pattern.

### SUMMARY OF THE INVENTION

Embodiments of the present invention are directed to providing a method for preventing a CD loss of a gate pattern during a gate patterning of a cell transistor in a nonvolatile memory.

Embodiments of the present invention are also directed to providing a method for fabricating a nonvolatile memory device, which is capable of preventing deformation of patterns by ensuring a masking margin even though an etch mask (hard mask) is formed to a relatively small thickness during a gate patterning of a cell transistor in a nonvolatile memory.

In accordance with an aspect of the present invention, there is provided a method for fabricating a nonvolatile memory device, the method including: forming a first conductive layer for a floating gate over a substrate; forming a charge blocking layer and a second conductive layer for a control gate over a resulting structure including the first conductive layer; forming an etch mask pattern over the second conductive layer; performing a primary etch process on the second conductive layer until the charge blocking layer is exposed; forming a passivation layer on a sidewall of the second conductive layer exposed by the primary etch process; and performing a secondary etch process on the charge blocking layer and the first conductive layer.

In accordance with another aspect of the present invention, there is provided a method for fabricating a nonvolatile memory device, the method including: forming a first polysilicon layer for a floating gate that is patterned to extend in a longitudinal direction over a substrate; forming a charge blocking layer and a second polysilicon layer for control gate over a resulting structure including the first polysilicon layer; forming an etch mask pattern extending in a transverse direction over the second polysilicon layer; performing a primary etch process on the second polysilicon layer until the charge blocking layer is exposed; forming a passivation layer on a sidewall of the second polysilicon layer exposed by the primary etch process; and performing a secondary etch process on the charge blocking layer, the remaining second polysilicon layer, and the first polysilicon layer.

In accordance with another aspect of the present invention, there is provided a method for fabricating a nonvolatile memory device, the method including: forming a charge blocking layer over a floating gate; forming a second conductive layer for a control gate over the charge block layer; performing a primary etch process on the second conductive layer until the charge blocking layer is exposed; forming a passivation layer on the second conductive layer exposed by the primary etch process; and performing a secondary etch process on the charge blocking layer, the second conductive layer, and the first conductive layer, wherein loss of a sidewall of the second polysilicon layer extending over the charge block layer is prevented by the passivation layer during the second etch process.

In accordance with another aspect of the present invention, the passivation layer prevents the top CD from being reduced by loss of the control gate in the secondary etch process. The passivation layer may be formed by the deposition process, instead of the oxidation process, in order to prevent the CD loss. The primary etch process, the process of forming the passivation layer, and the secondary etch process may be performed in-situ within the same equipment, without the wafer being exposed to atmosphere. The passivation layer may include a polymer thin film formed by a deposition process, or may include an oxide layer (for example, SiO2 thin film) formed by a deposition process. The passivation layer may be deposited on the sidewall of the second conductive layer (or the second polysilicon layer) and over the etch mask pattern.

### BRIEF DESCRIPTION OF THE DRAWINGS

FIGS. 1A to 1C are perspective views illustrating an etch process for forming a gate pattern of a cell transistor in a flash memory.

FIGS. 2A to 2C are images showing a cell transistor of a flash memory fabricated by a conventional method.

FIGS. 3A to 3C are perspective views illustrating a method for forming a gate of a cell transistor in accordance with an embodiment of the present invention.

FIGS. 4A and 4B are images showing that a larger top CD of a control gate is ensured, when gate patterns are formed under the same design rule by the method according to the prior art and the method in accordance with the embodiment of the present invention.

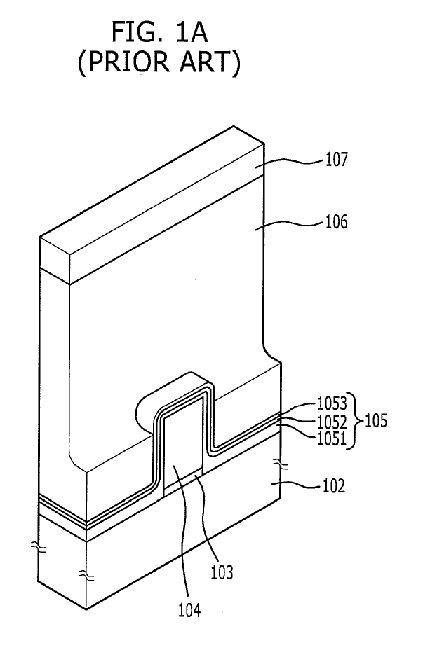

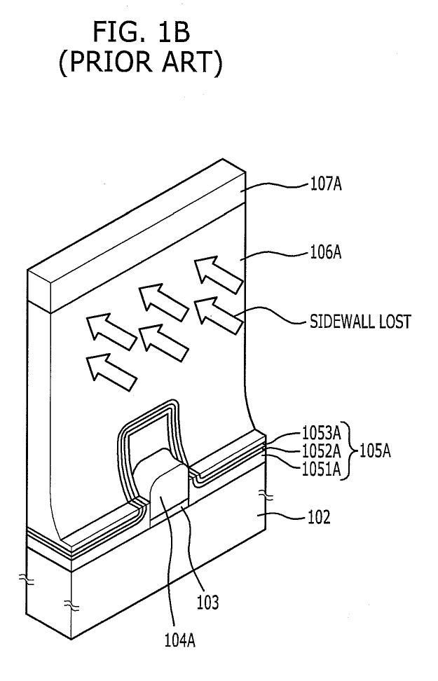

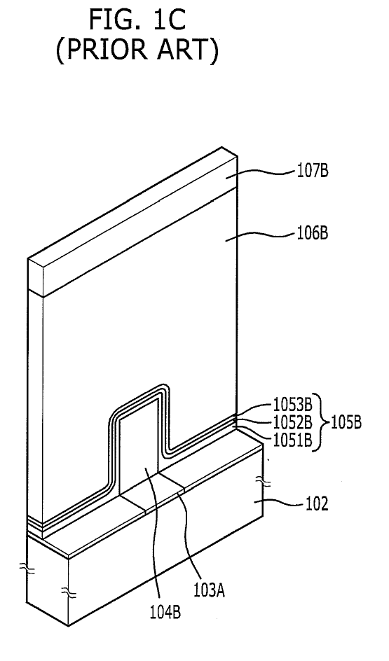

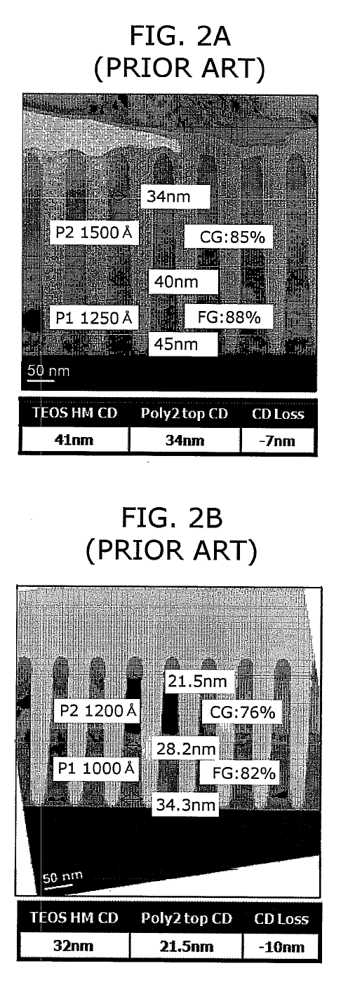

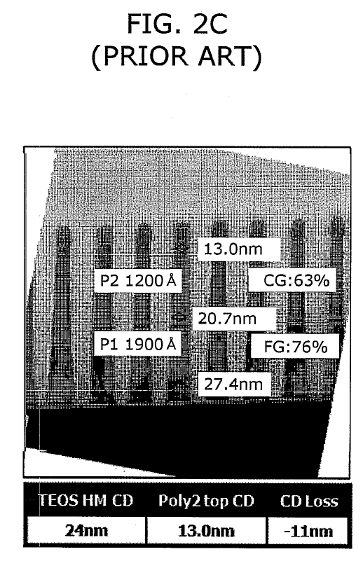

### DESCRIPTION OF SPECIFIC EMBODIMENTS

Other objects and advantages of the present invention can be understood by the following description, and become apparent with reference to the embodiments of the present invention.

Referring to the drawings, the illustrated thickness of layers and regions are exemplary and may not be exact. When a first layer is referred to as being “on” a second layer or “on” a substrate, it could mean that the first layer is formed directly on the second layer or the substrate, or it could also mean that a third layer may exist between the first layer and the substrate. Furthermore, the same or like reference numerals represent the same or similar constituent elements, although they may appear in different embodiments or drawings of the present invention.

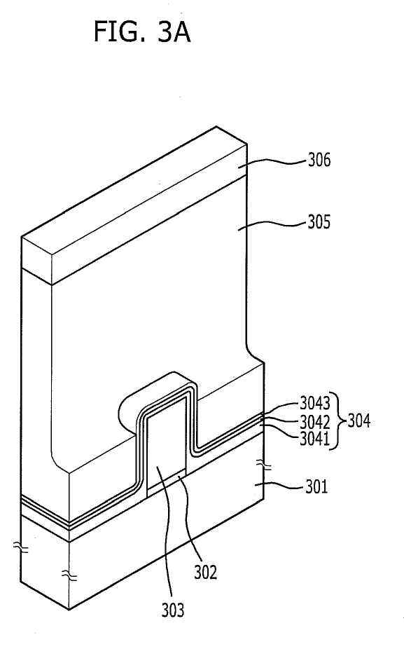

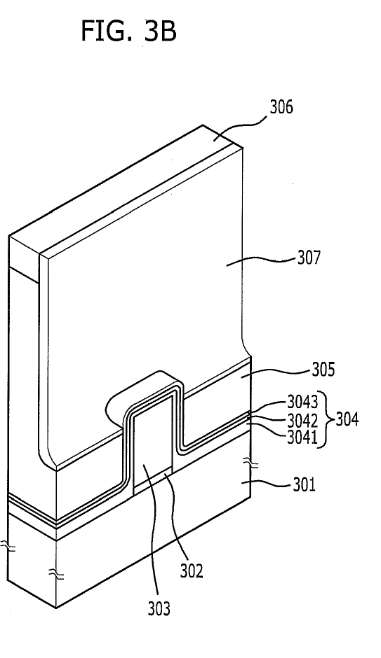

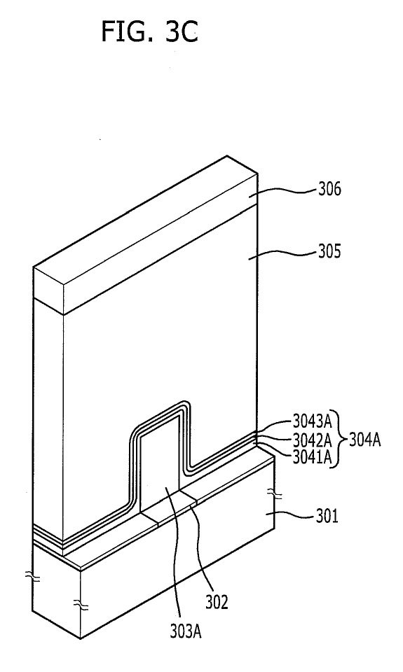

FIGS. 3A to 3C are perspective views illustrating a method for forming a gate of a cell transistor in accordance with an embodiment of the present invention. Referring to FIG. 3A, a first polysilicon layer 303 for a floating gate is patterned extending in a longitudinal direction. A substrate is a silicon substrate 301 and a tunnel insulation layer 302 is formed between the first polysilicon layer 303 and the substrate 301. A first ONO charge blocking layer 304 and a second polysilicon layer 305 are formed on a resulting structure including the first polysilicon layer 303 for floating gate. The first ONO charge blocking layer 304 includes an oxide layer 3041, a nitride layer 3042, and an oxide layer 3043. The first ONO charge blocking layer 304 is formed to a certain thickness on sidewalls and top of the first polysilicon layer 303 for patterned floating gate, and a second polysilicon layer 305 is formed to cover a resulting structure. The second polysilicon layer 305 is a layer that is primarily etched until the first ONO charge blocking layer 304 is exposed. A TEOS etch mask pattern 306 extending in a transverse direction is formed on the second polysilicon layer 305.

Referring to FIG. 3B, a passivation layer 307 is formed on sidewalls of the second polysilicon layer/conductive layer 305 exposed by a primary etch process on the second polysilicon layer 305. The passivation layer 307 is formed by a deposition process without CD loss with respect to the top of the second polysilicon layer 305 primarily etched. That is, in case where the passivation layer 307 is formed by an oxidation or nitridation process, the second polysilicon layer 305 may be lost. Thus, the second polysilicon layer 305 is formed by a deposition process, instead of the oxidation or nitridation process.

The passivation layer 307 formed by the deposition process may include polymer or oxide, and may be formed in-situ in the same equipment that has performed the primary etch process.

The passivation layer 307 may be formed of polymer by a treatment using one gas selected from the group comprising SiCl₄, SiF₄, COS, and SO₂ after the primary etch process.

The passivation layer 307 may be formed of oxide after the primary etch process by using a mixed gas of SiCl₄ and O₂, or may be formed by using a mixed gas of SiCl₄, O₂ and CH₄. Such an oxide formation is achieved by a deposition process, not an oxidation process.

The passivation layer 307 formed by the deposition process is also deposited on the TEOS etch mask pattern 306.

Referring to FIG. 3C, a final floating gate pattern 303A is formed by etching a second charge blocking layer 304A, a remaining second polysilicon layer 305, and the first polysilicon layer 303. The second charge blocking layer 304A includes an oxide pattern 3041A, a nitride pattern 3042A, and an oxide pattern 3043A which are formed by an etch process in such a state that the passivation layer 307 is etched. During such a secondary etch process, the passivation layer 307 prevents loss of the sidewalls of the second polysilicon layer 305, and functions to enhance the masking capability of the TEOS etch mask pattern 306. Therefore, the CD loss with respect to the top of the control gate can be suppressed, and the capability of etch masking can be maintained even though the TEOS thin film is thin. Meanwhile, the passivation layer 307 may be etched together by the secondary etch process and removed, or may be removed by a subsequent cleaning process. The primary etch process, the process of forming the passivation layer, and the secondary etch process may be performed in-situ.

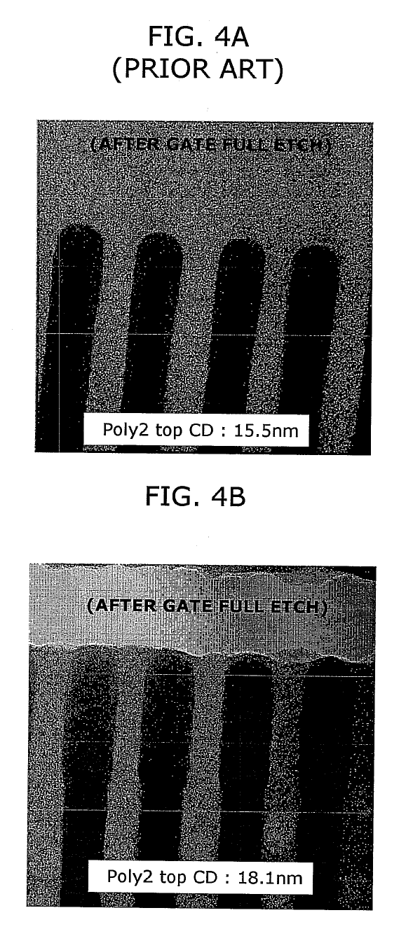

FIGS. 4A and 4B are images showing that a larger top CD of the control gate (poly2) is ensured, when the gate patterns are formed under the same design rule by the method according to the prior art and the method in accordance with the embodiment of the present invention. As can be seen from the comparison of FIG. 4A (prior art) and FIG. 4B (embodiment of the present invention), the top CD of the control gate (poly2) is relatively larger in the embodiment of the present invention than the prior art. Also, the TEOS layer (etch mask) remaining after the secondary etch process also remains thick, thereby ensuring the mask margin. FIG. 4B is an image showing a sample where the passivation layer is formed by a mixed gas of SiCl₄, O₂, and CH₄ after the primary etch process.

In the above mentioned embodiment, when the second polysilicon layer for control gate is patterned extending in a transverse direction in such a state that the first polysilicon layer for floating gate is patterned extending in a longitudinal direction, the first polysilicon layer is finally patterned. However, it can be easily understood by those skilled in the art that the technical spirit of the present invention is applicable to any process in which the three thin films are all etched and patterned in such a state that the floating gate, the charge blocking layer, and the control gate are sequentially stacked, in addition to the above-mentioned structure.

Furthermore, although it has been described in the above embodiment that the control gate and the floating gate are formed of polysilicon, they may also be formed of conductive materials other than polysilicon. The charge blocking layer can also be formed of thin films other than the ONO layer, and the etch mask may also be formed of thin films other than the TEOS thin film.

Moreover, except for the stacked structure of the first conductive layer, the charge blocking layer and the second conductive layer, the present invention can also be applied to other stacked structures including the three thin films and other thin films such as a barrier layer between the thin films.

In accordance with the embodiments of the present invention, when forming the gate pattern of the cell transistor in the nonvolatile memory where the floating gate, the charge blocking layer and the control gate are stacked, the CD loss of the top of the floating gate is suppressed and the degradation in the sheet resistance (Rs) of the floating gate is prevented. Accordingly, the high-speed operation and stable operation of the cell transistor in highly integrated devices whose cell size becomes smaller can be achieved.

Moreover, since the height of the etch mask pattern, that is, the thickness of the TEOS thin film can be relatively reduced, process defects such as wiggling of pattern can be prevented.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a nonvolatile memory device, the method comprising:
forming a first conductive layer for a floating gate over a substrate;
forming a charge blocking layer and a second conductive layer for a control gate over a resulting structure including the first conductive layer;
forming an etch mask pattern over the second conductive layer;
performing a primary etch process on the second conductive layer until the charge blocking layer is exposed;
forming a passivation layer on a sidewall of the second conductive layer exposed by the primary etch process; and
performing a secondary etch process on the charge blocking layer and the first conductive layer.

2. The method of claim 1, wherein the passivation layer is formed by a deposition process.

3. The method of claim 1, wherein the primary etch process and the secondary etch process are performed in-situ.

4. The method of claim 3, wherein the passivation layer is formed in-situ after the primary etch process.

5. The method of claim 1, wherein the passivation layer comprises a polymer thin film formed by a deposition process.

6. The method of claim 1, wherein the passivation layer comprises an oxide thin film formed by a deposition process.

7. The method of claim 1, wherein the charge blocking layer comprises an oxide-nitride-oxide (ONO) layer.

8. The method of claim 1, wherein the passivation layer is deposited over the sidewall of the second conductive layer and over the etch mask pattern.

9. The method of claim 1, wherein the charge blocking layer comprises an ONO layer, the first conductive layer and the second conductive layer comprise a polysilicon layer, the etch mask pattern comprises a tetra-ethyl-ortho-silicate (TEOS) layer and the passivation layer comprises a SiO₂ layer formed by a deposition process.

10. The method of claim 1, wherein the charge blocking layer comprises an ONO layer, the first conductive layer and the second conductive layer each comprise a polysilicon layer, the etch mask pattern comprises an TEOS layer and the passivation layer comprises a polymer layer.

11. A method for fabricating a nonvolatile memory device, the method comprising:
forming a first polysilicon layer for a floating gate that is patterned to extend in a longitudinal direction over a substrate;
forming a charge blocking layer and a second polysilicon layer for a control gate over a resulting structure including the first polysilicon layer;
forming an etch mask pattern extending in a transverse direction over the second polysilicon layer;
performing a primary etch process on the second polysilicon layer until the charge blocking layer is exposed;
forming a passivation layer on a sidewall of the second polysilicon layer exposed by the primary etch process; and
performing a secondary etch process on the charge blocking layer, the remaining second polysilicon layer, and the first polysilicon layer.

12. The method of claim 11, wherein the passivation layer is formed by a deposition process.

13. The method of claim 11, wherein the passivation layer comprises a polymer thin film.

14. The method of claim 13, wherein the passivation layer is formed after the primary etch process by using a gas selected from the group comprising SiCl₄, SiF₄, COS, and SO₂.

15. The method of claim 11, wherein the passivation layer comprises oxide.

16. The method of claim 15, wherein the passivation layer is formed after the primary etch process by using a mixed gas of SiCl₄ and O₂.

17. The method of claim 15, wherein the passivation layer is formed after the primary etch process by using a mixed gas of SiCl₄, O₂, and CH₄.

18. The method of claim 11, wherein the passivation layer is formed in-situ after the primary etch process.

19. The method of claim 11, wherein the passivation layer is deposited over the sidewall of the second polysilicon layer and over the etch mask pattern.

20. The method of claim 11, wherein the charge blocking layer comprises an ONO layer, the etch mask pattern comprises a TEOS layer and the passivation layer comprises a SiO₂ layer formed by a deposition process.

21. The method of claim 11, wherein the charge blocking layer comprises an ONO layer, the etch mask pattern comprises a TEOS layer and the passivation layer comprises a polymer layer.

22. A method for fabricating a nonvolatile memory device, the method comprising:
forming a charge blocking layer over a floating gate;
forming a second conductive layer for a control gate over the charge block layer;
performing a primary etch process on the second conductive layer until the charge blocking layer is exposed;
forming a passivation layer on the second conductive layer exposed by the primary etch process; and
performing a secondary etch process on the charge blocking layer, the second conductive layer, and the first conductive layer, wherein loss of a sidewall of the second polysilicon layer extending over the charge block layer is prevented by the passivation layer during the second etch process.

23. The method of claim 22, wherein the passivation layer is formed by a deposition process.
